(19) United States
(12) Patent Application Publication
(10) Pub. No.: US 2019/0138440 A1
(43) Pub. Date: May 9, 2019

(54) MEMORY SYSTEM AND OPERATING METHOD THEREOF

(71) Applicant: SK hynix Inc., Gyeonggi-do (KR)

(72) Inventor: Dong Sop LEE, Gyeonggi-do (KR)

(21) Appl. No.: 16/014,599

(22) Filed: Jun. 21, 2018

(30) Foreign Application Priority Data
Nov. 7, 2017 (KR) 10-2017-0147380

(51) Int. Cl. G06F 12/02; G06F 3/06; G11C 16/14; G11C 16/26; G11C 16/08; G06F 12/109

(52) U.S. Cl. CPC G06F 12/0246; G06F 3/0656; G06F 12/109; G11C 16/26; G11C 16/08; G11C 16/14

(57) ABSTRACT

A memory system and an operating method thereof are provided. The memory system includes a nonvolatile memory device, and a memory controller, wherein the memory controller comprises a host interface configured to receive a plurality of host requests provided according to a plurality of heterogeneous host interface protocols, a host translation layer configured to identify the plurality of heterogeneous host interface protocols and to translate the plurality of host requests into a meta request according to the identified heterogeneous host interface protocols, and a flash control section controlling the nonvolatile memory device based on the meta request.

### CROSS-REFERENCE TO RELATED APPLICATION

The present application claims priority under 35 U.S.C. § 119(a) to Korean patent application number 10-2017-0147380, filed on Nov. 7, 2017, which is incorporated herein by reference in its entirety.

### BACKGROUND

### Field of Invention

Various embodiments of the present disclosure generally relate to a memory system and an operating method thereof. Particularly, the embodiments relate to a memory system that communicates with a host according to any of a plurality of heterogeneous host interface protocols, and an operating method thereof.

### Description of Related Art

A nonvolatile memory device may include a plurality of memory blocks. Further, each memory block may include a plurality of memory cells, and an erase operation may be simultaneously performed on the memory cells included in a single memory block.

When a memory system receives a write command and a logical address from a host, the memory system may allocate a physical address corresponding to the logical address and may write data in a memory area corresponding to the physical address.

In addition, the memory system may receive host requests provided according to a plurality of heterogeneous host interface protocols from the host.

### SUMMARY

Various embodiments are directed to a memory system capable of processing one or more requests provided from a host according to one or more different host interface protocols, and an operating method thereof.

According to an embodiment, a memory system may include a nonvolatile memory device, and a memory controller, wherein the memory controller comprises a host interface configured to receive a plurality of host requests provided according to a plurality of heterogeneous host interface protocols, a host translation layer configured to identify the plurality of heterogeneous host interface protocols and to translate the plurality of host requests into a meta request according to the identified heterogeneous host interface protocols, and a flash control section controlling the nonvolatile memory device based on the meta request.

According to another embodiment, a method of operating a memory system includes receiving a host request from a host, determining a host interface protocol of the host request from among a plurality of host interface protocols based on an interface identification table, converting the host request into a meta request according to the determined host interface protocol, and controlling a nonvolatile memory device based on the meta request.

According to another embodiment, a memory system further includes a first host interface configured to receive a first host request according to a first host interface protocol, a second host interface configured to receive a second host request according to a second host interface protocol, and a host translation layer configured to identify the first and second host interface protocols and to translate the first and second host requests into a meta request, wherein the first host request and the second host request are for a same internal operation thereof.

According to another embodiment, a memory system includes a memory device that operates in response to a meta request, and a controller including an interface identification table having format information of different types of host interface protocols, wherein the controller translates an operation request provided according to one of the different types of host interface protocols into the meta request by using the interface identification table, and controls the memory device to perform an operation according to the meta request.

### BRIEF DESCRIPTION OF THE DRAWINGS

FIG. 1 is a diagram illustrating a memory system according to an embodiment of the present invention.

FIG. 2 is a diagram illustrating a memory controller of FIG. 1.

FIG. 3 is a diagram illustrating a memory system according to an embodiment of the present invention.

FIG. 4 is a diagram illustrating a nonvolatile memory device of FIG. 1.

FIG. 5 is a diagram illustrating a memory block of FIG. 4.

FIG. 6 is a diagram illustrating an operation of converting host requests provided according to a plurality of heterogeneous interface protocols to a meta request according to an embodiment of the present invention.

FIG. 7 is a diagram illustrating a memory controller according to an embodiment of the present invention.

FIG. 8 is a diagram illustrating a host interface according to an embodiment of the present invention.

FIG. 9 is a diagram illustrating a host interface according to an embodiment of the present invention.

FIG. 10 is a diagram illustrating a host translation layer according to an embodiment of the present invention.

FIG. 11 is a flowchart describing a write operation according to an embodiment of the present invention.

FIG. 12 is a flowchart describing a read operation according to an embodiment of the present invention.

FIGS. 13 to 16 are diagrams illustrating various application examples of the memory system according to one or more embodiments of the present invention.

### DETAILED DESCRIPTION

Various embodiments will be described in detail with reference to the accompanying drawings. Elements and features of the present disclosure, however, may be configured or arranged differently than shown in the illustrated embodiments. Thus, the present disclosure is not limited to the illustrated embodiments. Rather, the illustrated embodiments are provided so that this disclosure is thorough and complete and fully conveys the various aspects and features of the present invention to those skilled in the art. It is also noted that reference to “an embodiment” is not necessarily to only one embodiment, and different references to “an embodiment” are not necessarily to the same embodiment(s).

It is also noted that in this specification, “connected/coupled” refers to one component not only “directly coupling” another component but also “indirectly coupling” another component through one or more intermediate component(s). In addition, throughout the specification, when it is stated that a certain part “includes” a certain element, this does not exclude other elements; rather, the certain part may further include one or more other elements, unless stated otherwise.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments.

The terminology used herein is for the purpose of describing particular embodiments only and is not intended to be limiting of the present invention.

As used herein, singular forms may include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Hereinafter, the various embodiments of the present invention will be described in detail with reference to the attached drawings.

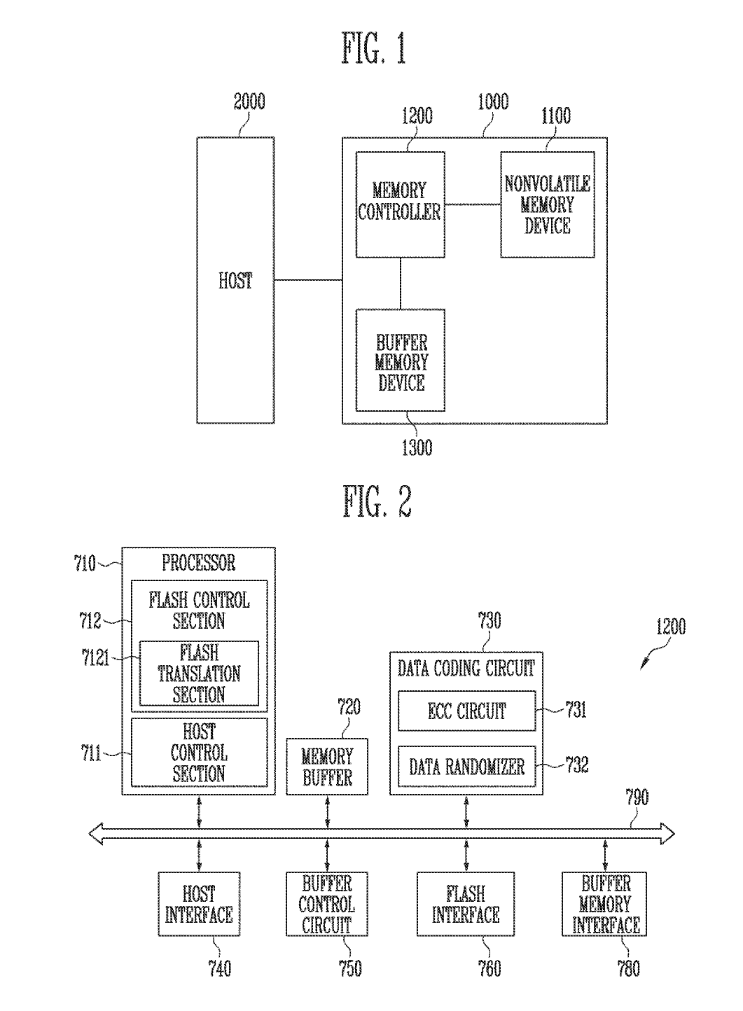

FIG. 1 is a diagram illustrating a memory system 1000 according to an embodiment of the present invention.

Referring to FIG. 1, the memory system 1000 may include a nonvolatile memory device 1100 retaining stored data even in the absence of power supply, a buffer memory device 1300 temporarily storing data, and a memory controller 1200 controlling the nonvolatile memory device 1100 and the buffer memory device 1300 in response to control of a host 2000.

The host 2000 may communicate with the memory system 1000 by using at least one of various communication methods such as a Universal Serial Bus (USB), a Serial AT Attachment (SATA), a Serial Attached SCSI (SAS), a High Speed Interchip (HSIC), a Small Computer System Interface (SCSI), a Peripheral Component Interconnection (PCI), a PCI express (PCIe), a NonVolatile Memory express (NVMe), a Universal Flash Storage (UFS), a Secure Digital (SD), a MultiMedia Card (MMC), an embedded MMC (e C), a Dual In-line Memory Module (DIMM), a Registered DIMM (RDIMM), and a Load Reduced DIMM (LRDIMM).

The memory controller 1200 may control overall operations of the memory system 1000 and may control a data exchange between the host 2000 and the nonvolatile memory device 1100. For example, the memory controller 1200 may program or read data by controlling the nonvolatile memory device 1100 in response to a request of the host 2000. Further, the memory controller 1200 may store information of main memory blocks and sub-memory blocks included in the nonvolatile memory device 1100 and may select the nonvolatile memory device 1100 to perform a program operation on a main memory block or a sub-memory block depending on the amount of data loaded for the program operation. According to an embodiment, the nonvolatile memory device 1100 may include a flash memory.

The memory controller 1200 may control a data exchange between the host 2000 and the buffer memory device 1300 or may temporarily store system data to control the nonvolatile memory device 1100 in the buffer memory device 1300. The buffer memory device 1300 may serve as an operation memory, a cache memory, or a buffer memory of the memory controller 1200. The buffer memory device 1300 may store codes and commands which the memory controller 1200 executes. Further, the buffer memory device 1300 may store the data processed by the memory controller 1200.

The memory controller 1200 may temporarily store data input from the host 2000 in the buffer memory device 1300, and may then transmit and store the data temporarily stored in the buffer memory device 1300 to the nonvolatile memory device 1100. The memory controller 1200 may receive the data and a logical address from the host 2000 and may convert the logical address to a physical address which indicates an area in the nonvolatile memory device 1100 where the data is actually stored. The memory controller 1200 may store a logical-physical address mapping table, configuring a mapping relationship between the logical address and the physical address, in the buffer memory device 1300.

According to an embodiment, the buffer memory device 1300 may include any of a Double Data Rate Synchronous Dynamic Random Access Memory (DDR SDRAM), a Double Data Rate4 Synchronous Dynamic Random Access Memory (DDR4 SDRAM), a Low Power Double Data Rate4 (LPDDR4) SDRAM, a Graphics Double Data Rate (GDDR) SDRAM, a Low Power DDR (LPDDR), and a Rambus Dynamic Random Access Memory (RDRAM).

Although FIG. 1 shows the buffer memory device 1300 included in the memory system 1000, the present invention is not limited thereto. That is, according to an embodiment, the buffer memory device 1300 may be separate from the memory system 1000.

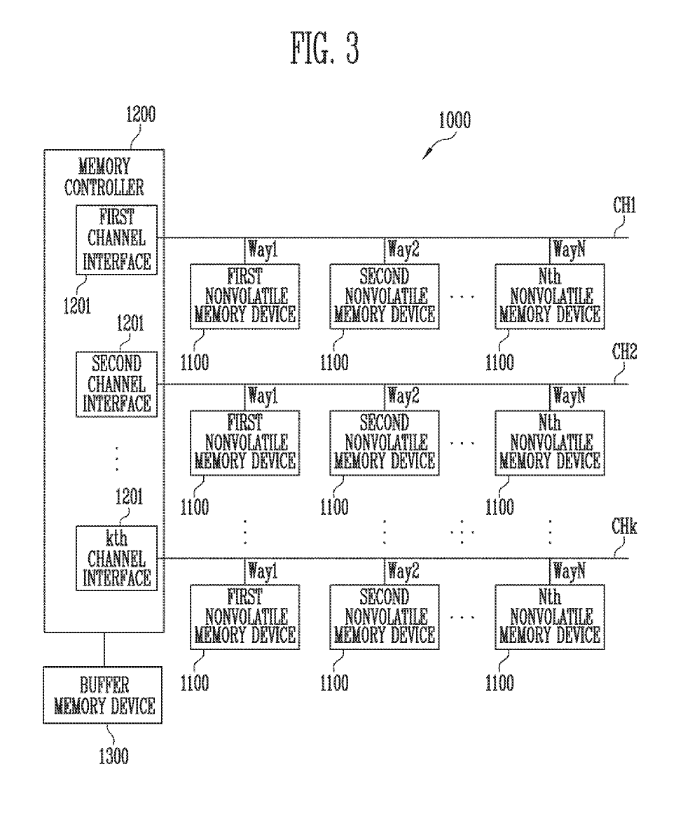

FIG. 2 is a diagram illustrating the memory controller 1200 of FIG.

Referring to FIG. 2, the memory controller 1200 may include a processor 710, a memory buffer 720, a data coding circuit 730, a host interface 740, a buffer control circuit 750, a flash interface 760, a buffer memory interface 780, and a bus 790. The data coding circuit 730 may include an error correction code (ECC) circuit 731 and a data randomizer 732.

The bus 790 may be configured to provide a channel between elements of the memory controller 1200.

The processor 710 may control all operations of the memory controller 1200 and may perform a logical operation. The processor 710 may communicate with the external host 2000 through the host interface 740 and may communicate with the nonvolatile memory device 1100 through the flash interface 760. Further, the processor 710 may communicate with the buffer memory device 1300 through the buffer memory interface 780. The processor 710 may control the memory buffer 720 through the buffer control circuit 750. The processor 710 may control the operations of the memory system 1000 by using the memory buffer 720 as an operation memory, a cache memory, or a buffer memory.

The processor 710 may queue the plurality of commands input from the host 2000. This operation may be called a multi-queue operation. The processor 710 may sequentially transfer the plurality of queued commands to the nonvolatile memory device 1100.

The memory buffer 720 may serve as an operation memory, a cache memory, or a buffer memory of the processor 710. The memory buffer 720 may store codes and commands which the processor 710 executes. The memory buffer 720 may store the data processed by the processor 710. The memory buffer 720 may include a Static RAM (SRAM) and/or a Dynamic RAM (DRAM).

The ECC circuit 731 may execute error correction. The ECC circuit 731 may execute ECC encoding based on the data to be written in the nonvolatile memory device 1100 through the flash interface 760. The ECC encoded data may be transferred to the nonvolatile memory device 1100 through the flash interface 760. The ECC circuit 731 may execute ECC decoding as to the data received from the nonvolatile memory device 1100 through the flash interface 760. The ECC circuit 731 may be included in the flash interface 760 as an element thereof.

The data randomizer 732 may randomize data or de-randomize the randomized data. The data randomizer 732 may perform a data randomizing operation on the data to be written in the nonvolatile memory device 1100 through the flash interface 760. The randomized data may be transferred to the nonvolatile memory device 1100 through the flash interface 760. The data randomizer 732 may perform a data de-randomizing operation on the data received from the nonvolatile memory device 1100 through the flash interface 760. The data randomizer 732 may be included in the flash interface 760 as an element thereof.

The host interface 740 may communicate with the external host 2000 in response to control of the processor 710. The host interface 740 may communicate with the external host 2000 by using at least one of various communication methods such as a Universal Serial Bus (USB), a Serial AT Attachment (SATA), a Serial Attached SCSI (SAS), a High Speed Interchip (HSIC), a Small Computer System Interface (SCSI), a Peripheral Component Interconnection (PCI), a PCI express (PCIe), a NonVolatile Memory express (NVMe), a Universal Flash Storage (UFS), a Secure Digital (SD), a MultiMedia Card (MMC), an embedded MMC (eMMC), a Dual In-line Memory Module (DIMM), a Registered DIMM (RDIMM), and a Load Reduced DIMM (LRDIMM).

The buffer control circuit 750 may control the memory buffer 720 in response to control of the processor 710.

The flash interface 760 may communicate with the nonvolatile memory device 1100 in response to control of the processor 710. The flash interface 760 may communicate commands, addresses, and data with the nonvolatile memory device 1100 through the channel.

Although FIG. 2 shows the memory controller 1200 including the memory buffer 720 and the buffer control circuit 750, the present invention is not limited thereto. That is, according to an embodiment, the memory buffer 720 and the buffer control circuit 750 may be provided separately.

For example, the processor 710 may control operations of the memory controller 1200 by using the codes. The processor 710 may load the codes from a nonvolatile memory device, such as a Read Only Memory (ROM), provided inside the memory controller 1200. In another example, the processor 710 may load the codes from the nonvolatile memory device 1100 through the flash interface 760.

The bus 790 of the memory controller 1200 may be divided into a control bus and a data bus. The data bus may transmit data in the memory controller 1200 and the control bus may transmit control information, such as a command and an address, in the memory controller 1200. The data bus and the control bus may be separated from each other so as to not interfere with or affect each other. The data bus may be coupled to the host interface 740, the buffer control circuit 750, the ECC circuit 731, the flash interface 760, and the buffer memory interface 780. The control bus may be coupled to the host interface 740, the processor 710, the buffer control circuit 750, the flash interface 760, and the buffer memory interface 780. Although FIG. 2 shows the memory controller 1200 including the buffer memory interface 780, the present invention is not limited thereto. That is, according to an embodiment, the buffer memory 780 may be provided separately.

The buffer memory interface 780 may communicate with the buffer memory device 1300 in response to control of the processor 710. The buffer memory interface 780 may communicate commands, addresses, and data with the buffer memory device 1300 through the channel.

The memory system 1000 may receive a write command, write data and the logical address from the host 2000. The memory controller 1200 may allocate a physical storage space of the nonvolatile memory device 1100 where the write data is stored, namely a memory block 110 or a page in response to the write command. In other words, the memory controller 1200 may map the physical address corresponding to the logical address in response to the write command. The physical address may be an address corresponding to the physical storage space of the nonvolatile memory device 1100 in which the write data received from the host 2000 is stored.

The memory system 1000 may store mapping information between the logical address and the physical address, namely logical-physical address mapping information in the memory block 110 of the nonvolatile memory device 1100. The memory block 110 storing the logical-physical address mapping information may be called a system block.

When the memory system 1000 is booted, the logical-physical address mapping information stored in the nonvolatile memory device 1100 may be loaded to the buffer memory device 1300 or the memory buffer 720. When it is necessary to check the logical-physical address mapping information stored in the nonvolatile memory device 1100, the memory system 1000 may load the logical-physical address mapping information from the nonvolatile memory device 1100 and may store the logical-physical address mapping information in the buffer memory device 1300 or the memory buffer 720. The buffer memory device 1300 and the memory buffer 720 may be collectively or individually called a controller buffer memory.

In another example, when the memory system 1000 receives the write command, the write data, and the logical address from the host 2000, the memory controller 1200 may allocate the physical storage space of the nonvolatile memory device 1100 in which the write data is stored in response to the write command. In other words, the memory controller 1200 may map the physical address corresponding to the logical address in response to the write command, and may update newly generated mapping information between the logical address and the physical address, namely the logical-physical address mapping information on the buffer memory device 1300 or the memory buffer 720.

The memory system 1000 may receive a read command and the logical address from the host 2000. In response to the read command, the memory system 1000 may check the physical address corresponding to the logical address from the logical-physical address mapping information stored in the nonvolatile memory device 1100, may read the data stored in the memory area corresponding to the physical address, and may output the read data to the host 2000.

The processor 710 may include a host control section 711 and a flash control section 712. The flash control section 712 may include a flash translation section 7121.

The host control section 711 may control data transmission between the host 2000 and the host interface 740, and the controller buffer memory. For example, the host control section 711 may control an operation of buffering the data input from the host 2000 through the host interface 740 into the memory buffer 720 or the buffer memory device 1300. In another example, the host control section 711 may control an operation of outputting the data buffered in the memory buffer 720 or the buffer memory device 1300 to the host 2000 through the host interface 740.

For example, in response to the write command, the host control section 711 may fetch the data provided from the host 2000 and may control an operation of buffering the data in the controller buffer memory. In addition, the host control section 711 may control an operation of outputting the data buffered in the controller buffer memory to the host 2000 in response to the write command. As noted above, the controller buffer memory may be the memory buffer 720 and/or the buffer memory device 1300.

The flash control section 712 may control an operation of transmitting and programming the data which is buffered in the controller buffer memory during a write operation to the nonvolatile memory device 1100. In another example, the flash control section 712 may control an operation of buffering in the controller buffer memory the data which is read and output from the nonvolatile memory device 1100 during the read operation.

The flash translation section 7121 may map the physical address corresponding to the logical address input from the host 2000 during a data write operation. The data may be written in the storage space corresponding to the mapped physical address in the nonvolatile memory device 1100. The flash translation section 7121 may check the physical address mapped to the logical address input from the host 2000 during the data write operation and may transmit the physical address to the flash control section 712. The flash control section 712 may read the data from the storage space corresponding to the physical address in the nonvolatile memory device 1100.

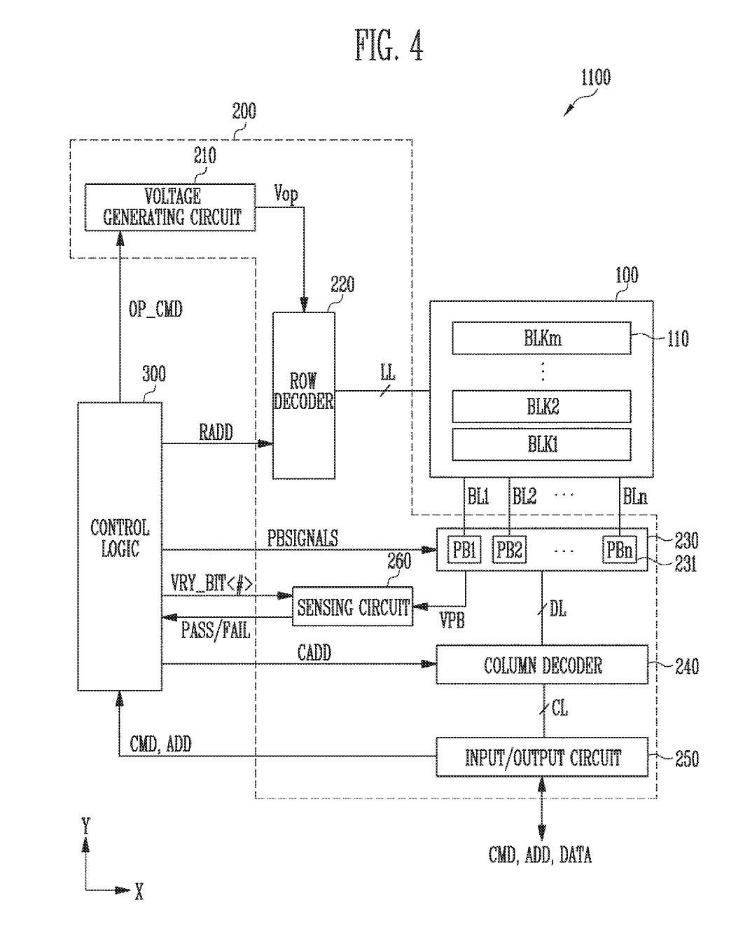

FIG. 3 is a diagram illustrating the memory system 1000 according to an embodiment of the present invention. More specifically, FIG. 3 illustrates the memory system 1000 including the memory controller 1200 and a plurality of nonvolatile memory devices 1100 coupled to the memory controller 1200 through a plurality of channels CH1 to CHk.

Referring to FIG. 3, the memory controller 1200 may communicate with the plurality of nonvolatile memory devices 1100 through the plurality of the channels CH1 to CHk. The memory controller 1200 may include a plurality of channel interfaces 1201, and each of the plurality of channels CH1 to CHk may be coupled to one of the plurality of channel interfaces 1201. For example, a first channel CH1 may be coupled to a first channel interface 1201, a second channel CH2 may be coupled to a second channel interface 1201, and a k^{th} channel CHk may be coupled to a k^{th} channel interface 1201, respectively. Each of the plurality of channels CH1 to CHk may be coupled to one or more nonvolatile memory devices 1100. The nonvolatile memory devices 1100 coupled to different channels may operate independently of each other. In other words, the nonvolatile memory device(s) 1100 coupled to the first channel CH1 and the nonvolatile memory device(s) 1100 coupled to the second channel CH2 may operate independently of each other. For example, the memory controller 1200 may communicate data or a command in parallel with a nonvolatile memory device 1100 through the second channel CH2 when the memory controller 1200 communicates the data or the command with a nonvolatile memory device 1100 through the first channel CH1.

Each of the plurality of channels CH1 to CHk may be coupled to a plurality of nonvolatile memory devices 1100. The plurality of nonvolatile memory devices 1100 coupled to a single channel may be configured in different ways. For example, N nonvolatile memory devices 1100 may be coupled to a single channel and each configured in one of N different ways. Namely, first to N^{th} nonvolatile memory devices 1100 may be coupled to the first channel CH1, with the first nonvolatile memory device 1100 configured in a first way (Way1), the second nonvolatile memory device 1100 configured in a second way (Way2), and the N^{th} nonvolatile memory device 1100 configured in an N^{th} way (WayN). Further, two or more nonvolatile memory devices 1100 may be configured in the same or a single way.

The first to N^{th} nonvolatile memory devices 1100 that share the first channel CH1 may sequentially communicate data or commands with the memory controller 1200, but not simultaneously in parallel. In other words, when the memory controller 1200 transmits data to the first nonvolatile memory device 1100 configured in the first way (Way1) through the first channel CH1, the second to N^{th} nonvolatile memory devices 1100 configured in the second to N^{th} ways (Way2 to WayN) of the first channel CH1 may not communicate data or commands with the memory controller 1200 through the first channel CH1. Namely, when one of the first to N^{th} nonvolatile memory devices 1100 sharing the first channel CH1 occupies the first channel CH1, the other nonvolatile memory devices 1100 coupled to the first channel CH1 may not use the first channel CH1.

The first nonvolatile memory device 1100 configured in Way1 of the first channel CH1 and the first nonvolatile memory device 1100 configured in Way1 of the second channel CH2 may communicate independently of each other with the memory controller 1200. In other words, the memory controller 1200 may exchange data with the Way1-configured nonvolatile memory device 1100 of the second channel CH2 through CH2 and the second channel interface 1201 at the same time as the memory controller 1200 exchanges data with the Way1-configured nonvolatile memory device 1100 of the first channel CH1 through CH1 and the first channel interface 1201.

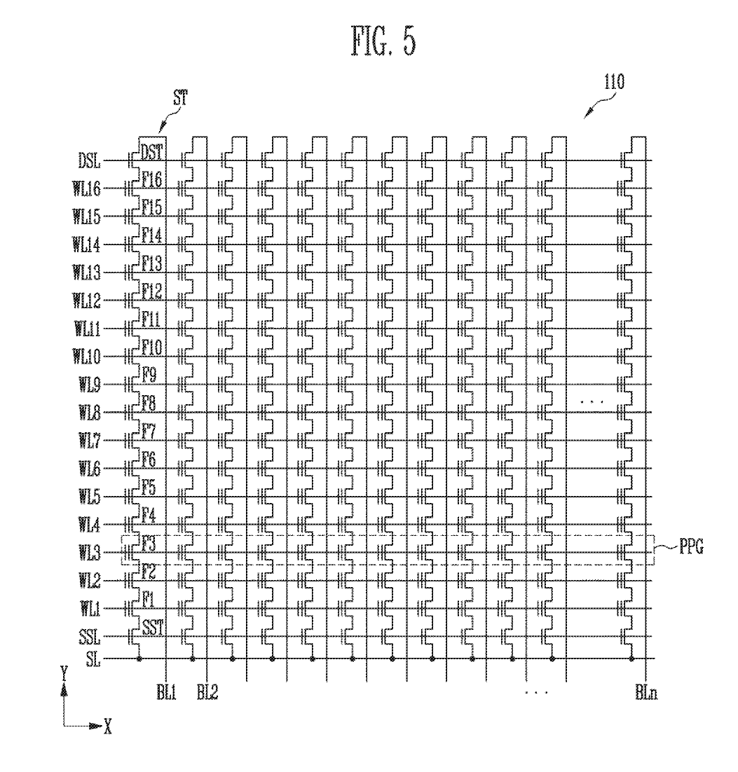

FIG. 4 is a diagram illustrating the nonvolatile memory device 1100 of FIG. 1.

Referring to FIG. 4, the nonvolatile memory device 1100 may include a memory cell array 100 in which the data is stored. The nonvolatile memory device 1100 may include peripheral circuits 200 that performs a program operation to store the data in the memory cell array 100, a read operation to output the stored data, and an erase operation to erase the stored data. The nonvolatile memory device 1100 may include a control logic 300 to control the peripheral circuits 200 in response to control of the memory controller 1200 of FIG.

The memory cell array 100 may include the plurality of memory blocks BLK1 to BLKm 110 (m is a positive integer). Each of the memory blocks BLK1 to BLKm 110 may be coupled to local lines LL and bit lines BL1 to BLn (n is a positive integer). For example, the local lines LL may include a first select line, a second select line, and a plurality of word lines arranged between the first select line and the second select line. The local lines LL may include dummy lines arranged between the first select line and the word lines and between the second select line and the word lines. The first select line may be a source select line and the second select line may be a drain select line. For example, the local lines LL may include the word lines, the drain select lines, the source select lines, and source lines. For example, the local lines LL may further include the dummy lines. For example, the local lines LL may further include pipe lines. The local lines LL may be coupled to the memory blocks BLK1 to BLKm 110, respectively, and the bit lines BL1 to BLn may be coupled in common to the memory blocks BLK1 to BLKm 110. The memory blocks BLK1 to BLKm 110 may have a two-dimensional or three-dimensional structure. For example, memory cells in the memory blocks 110 having the two-dimensional structure may be arranged in a parallel direction to a substrate. For example, the memory cells in the memory blocks 110 having the three-dimensional structure may be stacked in a vertical direction to the substrate.

The peripheral circuits 200 may perform program, read, and erase operations of a selected memory block 110 in response to control of the control logic 300. For example, in response to control of the control logic 300, the peripheral circuits 200 may provide a verify voltage and a pass voltage to the first select line, the second select line, and the word lines, may selectively discharge the first select line, the second select line, and the word lines, and may verify the memory cells coupled to a selected word line among the word lines. For example, the peripheral circuits 200 may include a voltage generating circuit 210, a row decoder 220, a page buffer group 230, a column decoder 240, an input/output circuit 250, and a sensing circuit 260.

The voltage generating circuit 210 may generate various operation voltages Vop used for program, read, and erase operations in response to an operation status read command OP_CMD. In addition, the voltage generating circuit 210 may selectively discharge the local lines LL in response to the operation status read command OP_CMD. For example, the voltage generating circuit 210 may generate a program voltage, a verify voltage, pass voltages, a turn-on voltage, a read voltage, an erase voltage, and a source line voltage in response to control of the control logic 300.

The row decoder 220 may transfer the operation voltages Vop to the local lines LL coupled to the selected memory block 110 in response to a row address RADD.

The page buffer group 230 may include a plurality of page buffers PB1 to PBn 231 coupled to the bit lines BL1 to BLn. The page buffers PB1 to PBn 231 may operate in response to page buffer control signals PBSIGNALS. For example, the page buffers PB1 to PBn 231 may temporarily store the data received through the bit lines BL1 to BLn or may sense a voltage or a current of the bit lines BL1 to BLn during a read or verify operation.

The column decoder 240 may transfer data between the input/output circuit 250 and the page buffer group 230 in response to a column address CADD. For example, the column decoder 240 may exchange data with the page buffers PB1 to PBn 231 through data lines DL or may exchange data with the input/output circuit 250 through column lines CL.

The input/output circuit 250 may transfer a command CMD and an address ADD received from the memory controller 1200 of FIG. 1 to the control logic 300 or may exchange data DATA with the column decoder 240.

The sensing circuit 260 may generate a reference current in response to an allowable bit VRY_BIT<#> during a read or verify operation and may output a pass signal PASS or a fail signal FAIL by comparing a sensing voltage VPB with a reference voltage generated by the reference current.

The control logic 300 may control the peripheral circuits 200 by outputting the operation status read command OP_CMD, the row address RADD, the page buffer control signals PBSIGNALS, and the allowable bit VRY_BIT<#> in response to the command CMD and the address ADD. Further, the control logic 300 may determine whether a verify operation passes or fails in response to the pass signal PASS or the fail signal FAIL.

In operating the nonvolatile memory device 1100, each memory block 110 may be a unit for an erase operation. In other words, the plurality of memory cells included in a single memory block 110 may be simultaneously erased from each other, but may not be selectively erased.

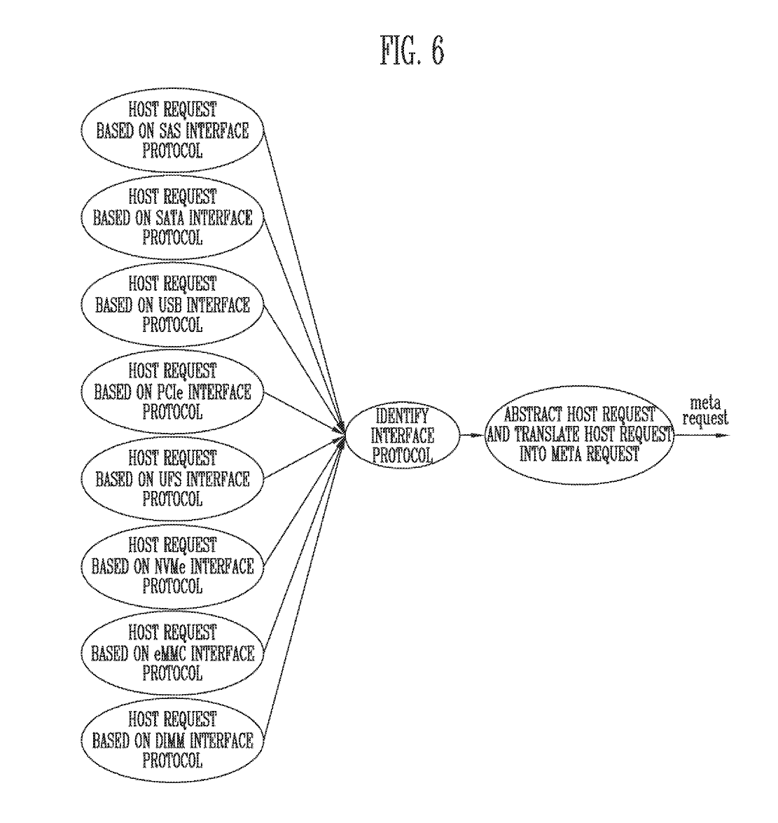

FIG. 5 is a diagram illustrating the memory block 110 of FIG. 4.

Referring to FIG. 5, in the memory block 110, the plurality of word lines arranged in parallel to one another may be coupled between the first select line and the second select line. The first select line may be a source select line SSL and the second select line may be a drain select line DSL. More specifically, the memory block 110 may include a plurality of strings ST coupled between the bit lines BL1 to BLn and a source line SL. The bit lines BL1 to BLn may be coupled to the strings ST, respectively, and the source line SL may be coupled in common to the strings ST. Since the strings ST may have the same configuration as one another, the string ST coupled to a first bit line BL1 will be described as an example.

The string ST may include a source select transistor SST, a plurality of memory cells F1 to F16, and a drain select transistor DST coupled in series between the source line SL and the first bit line BL1. A single string ST may include at least one of the source select transistors SST and the drain select transistors DST and may include more memory cells than the number of memory cells F1 to F16 as illustrated in FIG. 5.

A source of the source select transistor SST may be coupled to the source line SL, and a drain of the drain select transistor DST may be coupled to the first bit line BL1. The memory cells F1 to F16 may be coupled in series between the source select transistor SST and the drain select transistor DST. Gates of the source select transistors SST included in different strings ST may be coupled to the source select line SSL, gates of the drain select transistors DST may be coupled to the drain select line DSL, and gates of the memory cells F1 to F16 may be coupled to a plurality of word lines WL1 to WL16. A group of memory cells coupled to the same word line among the memory cells included in different strings ST may refer to a physical page PPG. Accordingly, the number of physical pages PPG included in the memory block 110 may be the same as the number of word lines WL1 to WL16.

A single memory cell may store one bit of data. Such a single memory cell may be generally called a single level cell (SLC). A single physical page PPG may store data of a single logical page LPG. The number of data bits included in the data of the single logical page LPG may be the same as the number of cells included in the single physical page PPG. A single memory cell may store two or more bits of data. Such a single memory cell may be generally called a multi-level cell (MLC). The single physical page PPG may store data of two or more logical pages LPG.

When the memory cell stores two bits of data, the single physical page PPG may include two pages PG. The single page PG may store the data of the single logical page LPG. The single memory cell may include one of a plurality of threshold voltages according to the data, and the plurality of pages PG included in the single physical page PPG may be expressed by differences of threshold voltages.

The plurality of memory cells included in the single physical page PPG may be simultaneously programmed. In other words, the nonvolatile memory device 1100 may perform a program operation in units of the physical page PPG. The plurality of memory cells included in the single memory block may be simultaneously erased. In other words, the nonvolatile memory device 1100 may perform an erase operation in units of the memory block 110. For example, in order to update a portion of data stored in the single memory block 110, the entire data stored in the memory block 110 may be read, data which is to be updated may be changed in the entire data, and then the entire data may be programmed in another memory block 110.

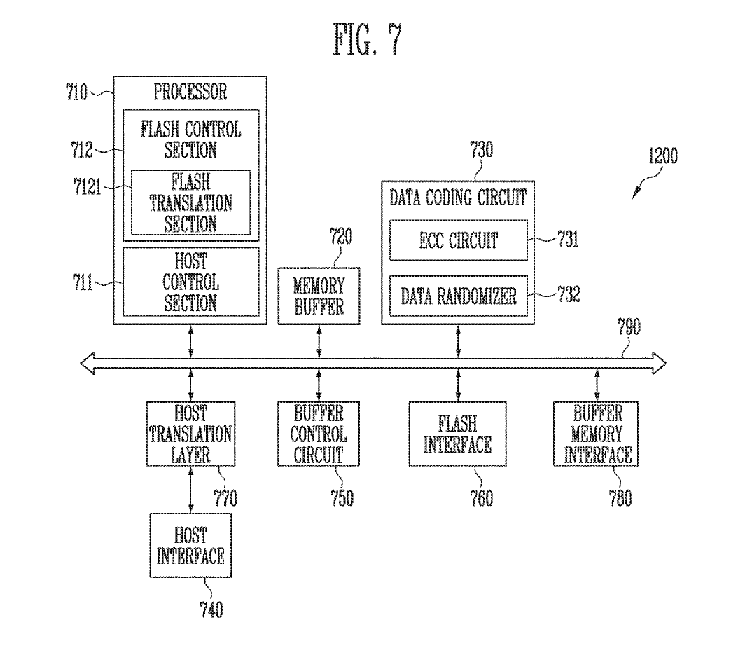

FIG. 6 is a diagram illustrating an operation of converting host requests provided according to a plurality of heterogeneous interface protocols to a meta request according to an embodiment of the present invention.

Referring to FIG. 6, the memory system 1000 may receive host requests provided from the host 2000 according to a plurality of heterogeneous interface protocols. Although the host requests are provided according to various interface protocols, the host requests may require the same operation of the memory system 1000. The memory system 1000 may convert such host requests into a meta request corresponding to an internal operation indicated by the host requests in the memory system 1000.

For example, from the host 2000, the memory system 1000 may receive a host request according to a SAS interface protocol, a host request according to a SATA interface protocol, a host request according to a USB interface protocol, a host request according to a PCIe interface protocol, a host request according to a UFS interface protocol, a host request according to an NVMe interface protocol, a host request according to an eMMC interface protocol, and a host request according to a DIMM interface protocol.

The memory system 1000 may identify the interface protocols of the host requests. In other words, the memory system 1000 may identify the interface protocol of each host request through an expression format of that host request. In another example, the memory system 1000 may receive information about the interface protocol of a particular host request from the host 2000, and may determine the interface protocol of that host request by such information.

For example, the memory system 1000 may include a table for the expression format of each of the host request interface protocols. The memory system 1000 may receive a host request from the host 2000 and then may identify the interface protocol of that host request based on the expression format of that host request and its associated interface protocol in the table.

The memory system 1000 may identify the interface protocol of the host request for accessing the memory system 1000 and then may convert the host request into a meta request. The meta request may correspond to an internal operation indicated by the host request in the memory system 1000. For example, a host request according to the SAS interface protocol may require a write operation within the memory system 1000, and a host request according to the NVMe interface protocol may also require the same write operation within the memory system 1000. In other words, although two host requests are provided according to different interface protocols and have different expression formats, the two host requests may require the same write operation within the memory system 1000. The meta request may correspond to the same write operation within the memory system 1000 indicated by the host request according to the SAS interface protocol or the host request according to the NVMe interface protocol.

The flash control section 712 of the memory controller 1200 may control the nonvolatile memory device 1100 based on the meta request.

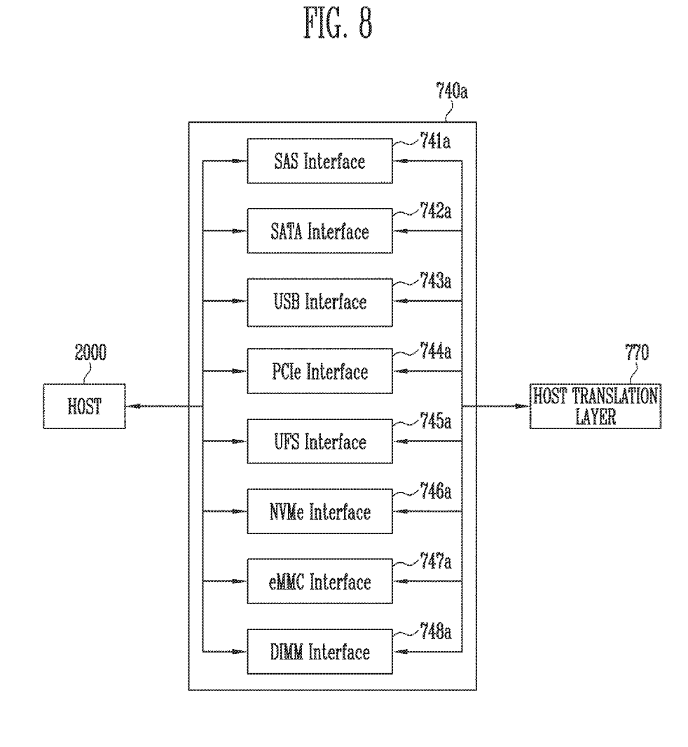

FIG. 7 is a diagram illustrating the memory controller 1200 according to an embodiment of the present invention.

Referring to FIG. 7, the memory controller 1200 shown in FIG. 2 may further include a host translation layer 770.

As described above with reference to FIG. 6, the memory system 1000 may communicate with at least one host 2000, each of which is configured to operate according to any of a plurality of heterogeneous host interface protocols. The memory system 1000 may receive one or more requests provided according to the plurality of heterogeneous host interface protocols. The host interface 740 may transfer commands and data between the memory system 1000 and the host 2000, both capable of operating according to the plurality of heterogeneous host interface protocols. For example, the host interface 740 may be coupled to the host 2000 through a plurality of pins, and the interface protocols may be different from each other depending on the coupling configuration between the host 2000 and the host interface 740. For example, when the host 2000 works with different interface protocols, the host interface 740 may be coupled to the host 2000 by the same coupling configuration. In other words, commands and data may be transferred in different formats between the memory system 1000 and the host 2000 according to different interface protocols through the same coupling configuration.

For example, the host interface 740 may receive the host request provided according to the SAS interface protocol, to transfer the received host request to the host translation layer 770, and to output a response signal generated according to the SAS interface protocol to the host 2000. In addition, the host interface 740 may receive the host request provided according to the SATA interface protocol, may transfer the received host request to the host translation layer 770, and may output a response signal generated according to the SATA interface protocol to the host 2000. The host interface 740 may perform the same operations as illustrated above on the USB interface protocol, the PCIe interface protocol, the UFS interface protocol, the NVMe interface protocol, the eMMC interface protocol, and the DIMM interface protocol.

In other words, the host interface 740 may be logically coupled to the host 2000 according to the plurality of different interface protocols through the same physical coupling configuration, may receive host requests in different formats input from the host 2000 according to the plurality of different interface protocols, and may transfer the received host requests to the host translation layer 770.

The host translation layer 770 may identify the interface protocols of the host requests received from the host interface 740 in various formats for accessing the memory system 1000. The memory system 1000 may identify the interface protocol of each host request through the expression format of that host request.

The host translation layer 770 may include a table for the expression formats of the host requests with respect to the interface protocols. The memory system 1000 may receive the host request from the host 2000 and identify the interface protocol of the host request based on the expression format of that host request and the associated interface protocol in the table. Accordingly, the host translation layer 770 may translate the host request into a meta request. The meta request may correspond to an internal operation indicated by the host request in the memory system 1000. The host translation layer 770 may transmit the meta request to the flash control section 712 and the flash control section 712 may control the nonvolatile memory device 1100 based on the meta request.

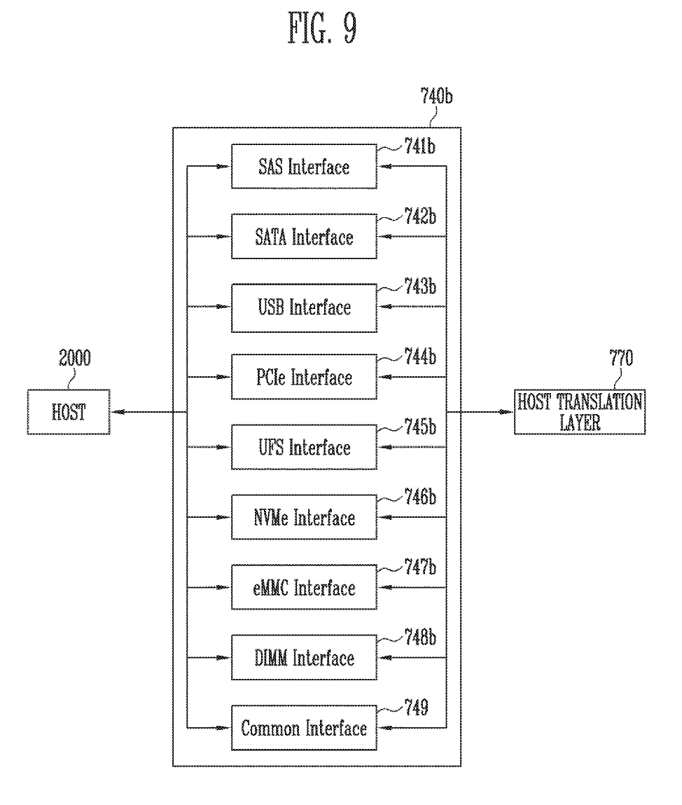

FIG. 8 is a diagram illustrating a host interface 740a according to an embodiment of the present invention.

Referring to FIG. 8, the host interface 740a may include a SAS interface 741a and a SATA interface 742a.

The SAS interface 741a may receive the host request provided according to the SAS interface protocol, transfer the received host request to the host translation layer 770, and output a response signal generated according to the SAS interface protocol to the host 2000.

The SATA interface 742a may receive the host request provided according to the SATA interface protocol, transfer the received host request to the host translation layer 770, and output a response signal generated according to the SATA interface protocol.

The host interface 740a may further include a USB interface 743a and a PCIe interface 744a.

The USB interface 743a may receive the host request provided according to the USB interface protocol, transfer the received host request to the host translation layer 770, and output a response signal generated according to the USB interface protocol to the host 2000.

The PCIe interface 744a may receive the host request provided according to the PCIe interface protocol, transfer the received host request to the host translation layer 770, and output a response signal generated according to the PCIe interface protocol to the host 2000.

The host interface 740a may further include a UFS interface 745a, an NVMe interface 746a, an eMMC interface 747a, and a DIMM interface 748a.

The UFS interface 745a may receive the host request provided according to the UFS interface protocol, transfer the received host request to the host translation layer 770, and output a response signal generated according to the UFS interface protocol to the host 2000.

The NVMe interface 746a may receive the host request provided according to the NVMe interface protocol, transfer the received host request to the host translation layer 770, and output a response signal generated according to the NVMe interface protocol to the host 2000.

The eMMC interface 747a may receive the host request provided according to the eMMC interface protocol, transfer the received host request to the host translation layer 770, and output a response signal generated according to the eMMC interface protocol to the host 2000.

The DIMM interface 748a may receive the host request provided according to the DIMM interface protocol, transfer the received host request to the host translation layer 770, and output a response signal generated according to the DIMM interface protocol to the host 2000.

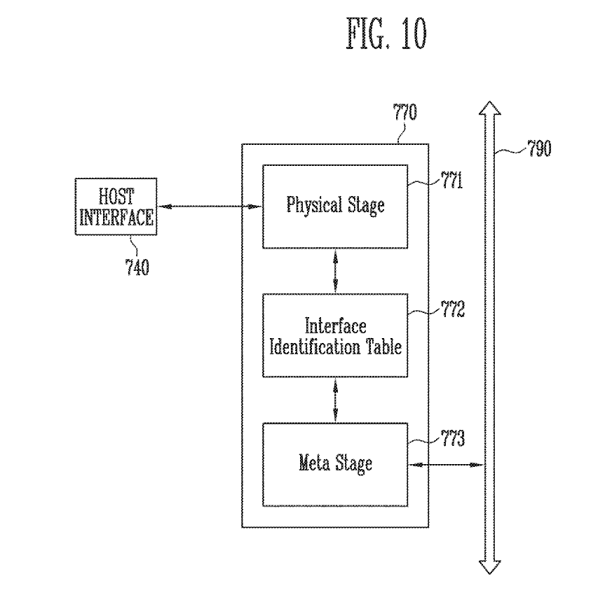

FIG. 9 is a diagram illustrating a host interface 740b according to an embodiment of the present invention.

Referring to FIG. 9, the host interface 740b may include a common interface 749. Two or more interface protocols among the SAS interface protocol, the SATA interface protocol, the USB interface protocol, the PCIe interface protocol, the UFS interface protocol, the NVMe interface protocol, the eMMC interface protocol, and the DIMM interface protocol may include a common protocol format. In other words, schemes of processing a write command of heterogeneous host interface protocols may be different from each other, but a scheme of processing a write data of heterogeneous host interface protocols may be same. In this case, a single circuit configuration for storing write data into the nonvolatile memory device 1100 may be provided for the heterogeneous interface protocols.

In another example, all the heterogeneous interface protocols may use a chip enable (CE) configuration such as a CE pin. In this example, in the host interface 740 a single CE configuration may be provided to be shared by the respective interface protocols rather than providing a separate CE configuration for each of the supported interface protocols. In another example, the heterogeneous interface protocols may have the same scheme of processing write commands but may have different schemes of processing read commands. In this case, a single circuit configuration for processing the write commands may be provided in the common interface 749 while different circuit configurations for processing the read commands may be independently provided for the heterogeneous interface protocols.

In other words, a single circuit with a configuration common to two or more interfaces among a SAS interface 741b, a SATA interface 742b, a USB interface 743b, a PCIe interface 744b, a UFS interface 745b, an NVMe interface 746b, an eMMC interface 747b, and a DIMM interface 748b may be provided. The common interface 749 may include the common circuit configuration.

In this example, the SAS interface 741b, the SATA interface 742b, the USB interface 743b, the PCIe interface 744b, the UFS interface 745b, the NVMe interface 746b, the eMMC interface 747b, and the DIMM interface 748b may respectively include different circuit configurations to support different configurations among the interface protocols.

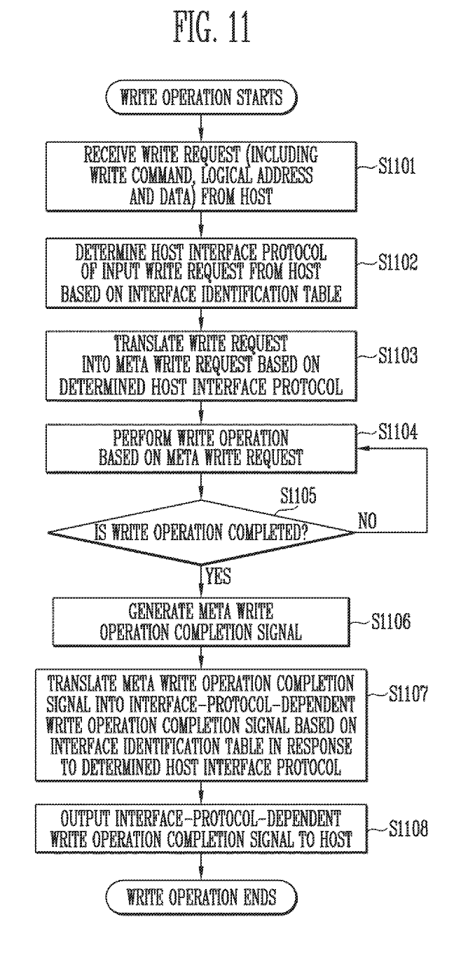

FIG. 10 is a diagram illustrating the host translation layer 770 according to an embodiment of the present invention.

Referring to FIG. 10, the host translation layer 770 may include a physical stage 771, an interface identification table 772, and a meta stage 773.

The physical stage 771 may receive a host request from the host 2000 through the host interface 740. The host translation layer 770 may determine the interface protocol of the host request for accessing the memory system 1000 by identifying the host request based on the interface identification table 772. The meta stage 773 may translate the host request into a meta request based on the interface protocol determined based on the interface identification table 772 and may transfer the meta request to the processor 710, more specifically, to the flash control section 712 in the processor 710.

The meta request generated by the meta stage 773 may correspond to the internal operation of the memory system 1000 indicated by the host requests provided according to the plurality of heterogeneous interface protocols. Although the host requests are of different formats according to different heterogeneous interface protocols, the host requests may require the same internal operation of the memory system 1000. Namely, the meta request may indicate the actually required internal operation by abstracting the host requests of the different heterogeneous interface protocols.

As described above, the host translation layer 770 may translate the host requests provided according to the plurality of heterogeneous interface protocols into the meta request, and may transfer the meta request to the flash control section 712 in the processor 710. Accordingly, the flash control section 712 may be configured independently of the types of the interface protocols. Therefore, the flash control section 712 may be configured without consideration of the interface protocols. For example, when a new interface protocol is defined later, the flash control section 712 of the processor 710 may be used without a change, whereas the configuration of the host translation layer 770 of the memory system 1000 may change. According to this example, the configuration of the host translation layer 770 may be changed by a firmware update, which may increase adaptability of the memory system 1000 to a new interface protocol.

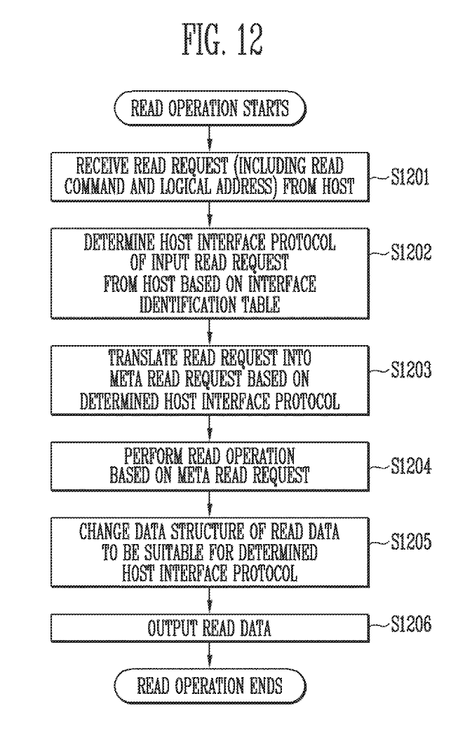

FIG. 11 is a flowchart illustrating a write operation according to an embodiment of the present invention.

Referring to FIG. 11, the host interface 740 of the memory system 1000 may receive a write request from the host 2000 at step S1101. The write request may include a write command, a logical address and data. The host interface 740 may transfer the write request to the host translation layer 770.

The host translation layer 770 may determine a type of a host interface protocol of the write request input from the host 2000 based on the interface identification table 772 at step S1102. For example, the host translation layer 770 may determine a type of the host interface protocol of the host request by inputting an expression format of the write request to the interface identification table 772 to identify the type of the host interface protocol in the table.

The host translation layer 770 may translate the write request into a meta write request according to the determined host interface protocol at step S1103. The meta write request may correspond to a substantial internal write operation of the memory system 1000 indicated by the host request. The host translation layer 770 may transfer the meta write request to the flash control section 712.

The flash control section 712 may perform a write operation on the data by controlling the nonvolatile memory device 1100 or the buffer memory device 1300 based on the meta write request transferred from the host translation layer 770 at step S1104. The flash translation section 7121 of the flash control section 712 may map the logical address, which is input from the host 2000, to a physical address and the flash control section 712 may perform the write operation based on the mapped physical address. The physical address may indicate a storage space inside the nonvolatile memory device 1100 where the data is written. The flash translation section 7121 may map the logical address, the host interface protocol of which is determined through the host translation layer 770, to the physical address.

When the write operation is completed (‘Yes’ at step S1105), the flash control section 712 may generate a meta write operation completion signal at step S1106. In addition, the flash control section 712 may transfer the meta write operation completion signal to the host translation layer 770.

The host translation layer 770 may translate the meta write operation completion signal into an interface-protocol-dependent write operation completion signal according to the host interface protocol determined from the interface identification table 772 at step S1107. In addition, the host translation layer 770 may transfer the interface-protocol-dependent write operation completion signal to the host interface 740.

The host interface 740 may output the interface-protocol-dependent write operation completion signal transferred from the host translation layer 770 to the host 2000 at step S1108. After that, the write operation may be finished.

When the write operation is not completed (‘No’ at step S1105), the meta write operation completion signal may not be generated until the write operation is completed. In other words, when the write operation is not completed, the operation returns to step S1104 in which write operation is performed based on the meta write request.

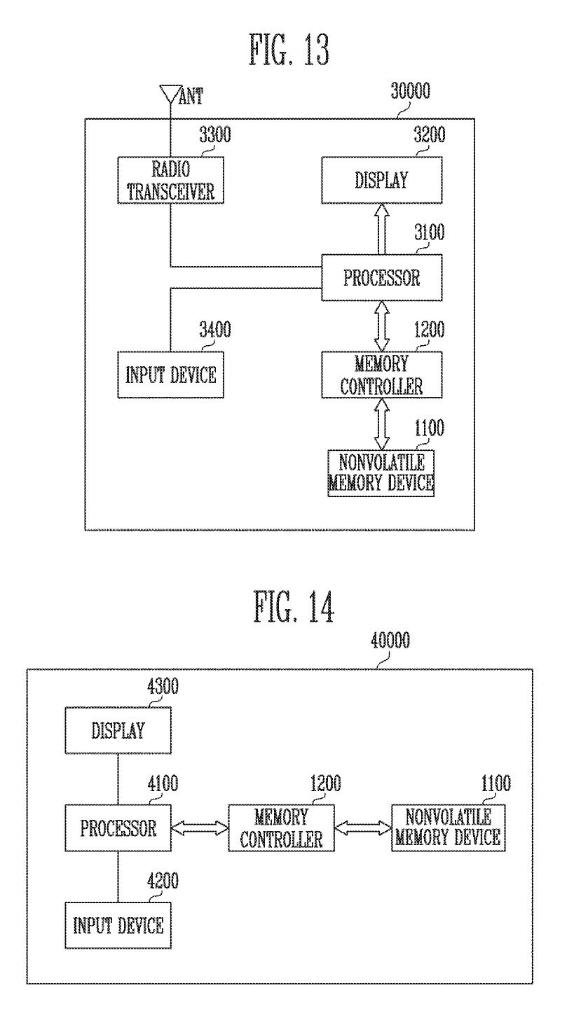

FIG. 12 is a flowchart illustrating a read operation according to an embodiment of the present invention.

Referring to FIG. 12, the host interface 740 of the memory system 1000 may receive a read request from the host 2000 at step S1201. The read request may include a read command and a logical address. The host interface 740 may transfer the read request to the host translation layer 770.

The host translation layer 770 may determine a type of a host interface protocol of the host request based on the interface identification table 772 at step S1202. For example, the host translation layer 770 may determine a type of the host interface protocol of the host request by inputting an expression format of the read request to the interface identification table 772.

The host translation layer 770 may translate the read request into a meta read request according to the determined host interface protocol at step S1203. The meta read request may correspond to a substantial internal read operation of the memory system 1000 indicated by the host request. In addition, the host translation layer 770 may transfer the meta read request to the flash control section 712.

The flash control section 712 may perform a read operation by controlling the nonvolatile memory device 1100 and the buffer memory device 1300 based on the meta read request at step S1204. The flash translation section 7121 of the flash control section 712 may find a physical address corresponding to the logical address, which is input from the host 2000 according to the host interface protocol and translated into the meta request by the host translation layer 770, and the flash control section 712 may perform the read operation based on the physical address. The physical address may indicate a storage space inside the nonvolatile memory device 1100 where the data to be read is stored. In addition, the flash translation section 7121 may find the physical address corresponding to the logical address, the host interface protocol of which is determined through the host translation layer 770.

The flash control section 712 may change a data structure of read data to be suitable for the determined host interface protocol at step S1205.

Then, the host control section 711 may control output of the read data through the host interface 740 at step S1206.

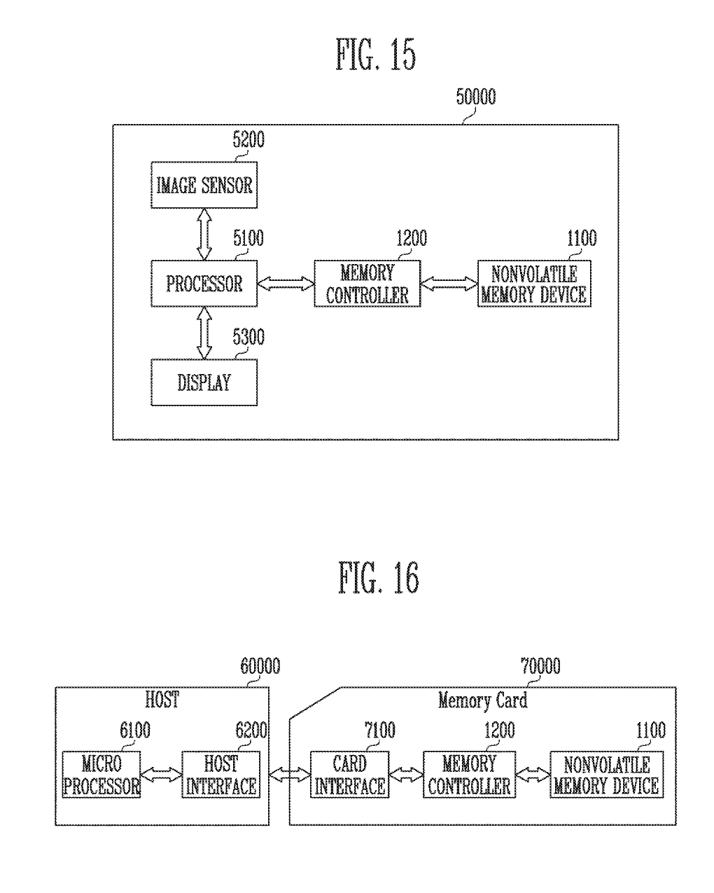

FIG. 13 is a diagram illustrating an application example of a memory system according to one or more embodiments of the present invention.

Referring to FIG. 13, a memory system 30000 may be embodied in a cellular phone, a smart phone, a tablet PC, a personal digital assistant (PDA), or a wireless communication device. The memory system 30000 may include the nonvolatile memory device 1100 and the memory controller 1200 to control operations of the nonvolatile memory device 1100. The memory controller 1200 may control data access operations of the nonvolatile memory device 1100, for example, program, erase, and read operations, in response to control of a processor 3100.

The data programmed to the nonvolatile memory device 1100 may be output through a display 3200 in response to control of the memory controller 1200.

A radio transceiver 3300 may exchange radio signals through an antenna ANT. For example, the radio transceiver 3300 may convert a radio signal received through the antenna ANT into a signal which the processor 3100 processes. The processor 3100 may process the signal output from the radio transceiver 3300 and transmit the processed signal to the memory controller 1200 or the display 3200. The memory controller 1200 may program the signal processed by the processor 3100 to the nonvolatile memory device 1100. The radio transceiver 3300 may convert the signal output from the processor 3100 into the radio signal and may output the converted radio signal to an external device through the antenna ANT. An input device 3400 may input the control signal to control the operation of the processor 3100 or the data to be processed by the processor 3100, and may be embodied as a pointing device such as a touch pad and a computer mouse, a keypad, or a keyboard. The processor 3100 may control the operations of the display 3200 so that the data output from the memory controller 1200, the data output from the radio transceiver 3300, or the data output from the input device 3400 may be output to the display 3200.

According to an embodiment, the memory controller 1200 which controls the operations of the nonvolatile memory device 1100 may be formed as a portion of the processor 3100, or may be a separate chip from the processor 3100. Further, the memory controller 1200 may be embodied according to the example of the memory controller 1200 illustrated in FIG. 2.

FIG. 14 is a diagram illustrating an application example of a memory system according to one or more embodiments of the present invention.

Referring to FIG. 14, a memory system 40000 may be embodied in a personal computer (PC), a tablet PC, a net-book, an e-reader, a personal digital assistant (PDA), a portable multimedia player (PMP), an MP3 player, or an MP4 player.

The memory system 40000 may include the nonvolatile memory device 1100 and the memory controller 1200 to control data processing operations of the nonvolatile memory device 1100.

A processor 4100 may output the data stored in the nonvolatile memory device 1100 through a display 4300 depending on the data input through an input device 4200. The input device 4200 may be embodied as a pointing device such as a touch pad or a computer mouse, a keypad, or a keyboard.

The processor 4100 may control the overall operation of the memory system 40000 and the operations of the memory controller 1200. According to an embodiment, the memory controller 1200 that controls the operation of the nonvolatile memory device 1100 may be formed as a portion of the processor 4100 or as a separate chip from the processor 4100. Further, the memory controller 1200 may be embodied according to the example of the memory controller 1200 as illustrated in FIG. 2.

FIG. 15 is a diagram illustrating an application example of a memory system according to one or more embodiments of the present invention.

Referring to FIG. 15, a memory system 50000 may be embodied in an image processing device such as a digital camera, a cellular phone with a digital camera, a smartphone with a digital camera, or a tablet PC with a digital camera.

The memory system 50000 may include the memory device 1100 and the memory controller 1200 to control data processing operations of the nonvolatile memory device 100, for example, program, erase and read operations.

An image sensor 5200 of the memory system 50000 may convert an optical image to digital signals, and the converted digital signals may be transmitted to a processor 5100 or the memory controller 1200. In response to control of the processor 5100, the converted digital signals may be output through a display 5300 or may be stored in the nonvolatile memory device 1100 through the memory controller 1200. The data stored in the nonvolatile memory device 1100 may be output through the display 5300 in response to control of the processor 5100 or the memory controller 1200.

According to an embodiment, the memory controller 1200 that controls the operations of the nonvolatile memory device 1100 may be formed as a portion of the processor 5100 or a separate chip from the processor 5100. Further, the memory controller 1200 may be embodied according to the example of the memory controller 1200 as illustrated in FIG. 2.

FIG. 16 is a diagram illustrating an application example of a memory system according to one or more embodiments of the present invention.

Referring to FIG. 16, a memory system 70000 may be embodied as a memory card or a smart card. The memory system 70000 may include the memory device 1100, the memory controller 1200, and a card interface 7100.

The memory controller 1200 may control an exchange of data between the nonvolatile memory device 1100 and the card interface 7100. According to an embodiment, the card interface 7100 may be a secure digital (SD) card interface or a multi-media card (MMC) interface, but is not limited to these interfaces. Further, the memory controller 1200 may be embodied according to the example of the memory controller 1200 as illustrated in FIG. 2.

The card interface 7100 may interface with a data exchange between a host 60000 and the memory controller 1200 depending on a protocol of the host 60000. According to an embodiment, the card interface 7100 may support a Universal Serial Bus (USB) protocol and an InterChip (IC)-USB protocol. The card interface 7100 may be hardware which supports the protocol that the host 60000 uses, software mounted on the hardware, or a signal transmitting method.

When the memory system 70000 accesses a host interface 6200 of the host 60000 such as a PC, a tablet PC, a digital camera, a digital audio player, a cellular phone, console video game hardware, or a digital set-top box, the host interface 6200 may perform data communication with the nonvolatile memory device 1100 through the card interface 7100 and the memory controller 1200 in response to control of a microprocessor 6100.

As described above, according to embodiments of the present disclosure, configuration and operation performance of a memory controller may be improved by identifying a plurality of heterogeneous interface protocols and converting a host request into a meta request in association with an operation of a memory system.

Various embodiments have been disclosed, and although specific terms are employed, various changes in forms and details may be made to the above-described examples of embodiments without departing from the spirit and scope of the present invention. Accordingly, it will be understood by those skilled in the art that the scope of the present invention should not be limited to the above-described embodiments, and instead be construed to cover modifications and variations within the scope of the following claims and their equivalents.

What is claimed is:

1. A memory system, comprising:
a nonvolatile memory device; and
a memory controller,
wherein the memory controller comprises:
a host interface configured to receive a plurality of host requests provided according to a plurality of heterogeneous host interface protocols;
a host translation layer configured to identify the plurality of heterogeneous host interface protocols and to translate the plurality of host requests into a meta request according to the identified heterogeneous host interface protocols; and
a flash control section controlling the nonvolatile memory device based on the meta request.

2. The memory system of claim 1, wherein the host translation layer identifies the plurality of heterogeneous host interface protocols based on expression formats of the plurality of host requests.

3. The memory system of claim 1,
wherein the plurality of host requests corresponds to a single internal operation, and
wherein the meta request corresponds to the single internal operation.

4. The memory system of claim 3, wherein the host translation layer comprises an interface identification table and is configured to identify the plurality of heterogeneous host interface protocols based on the interface identification table.

5. The memory system of claim 3, wherein the plurality of heterogeneous host interface protocols comprises two or more interfaces among a SAS interface, a SATA interface, a PCIe interface, a UFS interface, an NVMe interface, and an eMMC interface.

6. The memory system of claim 1, wherein the flash control section is configured independently of differences among the plurality of heterogeneous host interface protocols.

7. The memory system of claim 1, wherein a pin configuration coupling the host interface and a host is the same for each of the plurality of heterogeneous host interface protocols.

8. The memory system of claim 1, wherein the flash control section comprises a flash translation section,
wherein the host interface receives a logical address from a host,
wherein the flash translation section is configured to translate the logical address into a physical address based on the identified heterogeneous host interface protocols, and
wherein the flash control section controls the nonvolatile memory device based on the physical address.

9. A method of operating a memory system, the method comprising:
receiving a host request from a host;
determining a host interface protocol of the host request from among a plurality of host interface protocols based on an interface identification table;
converting the host request into a meta request according to the determined host interface protocol; and
controlling a nonvolatile memory device based on the meta request.

10. The method of claim 9, wherein the meta request refers to an internal operation corresponding to the host request, and the meta request is configured independently of differences among the plurality of host interface protocols.

11. The method of claim 9, further comprising:
converting a completion signal according to the determined host interface protocol when an internal operation for the meta request is completed; and
outputting a converted completion signal to the host.

12. The method of claim 9, wherein the plurality of host interface protocols comprises two or more interfaces among a SAS interface, a SATA interface, a PCIe interface, a UFS interface protocol, an NVMe interface protocol, and an eMMC interface protocol.

13. The method of claim 9, wherein the determining is performed based on an expression format of the host request.

14. A memory system, comprising:
a first host interface configured to receive a first host request according to a first host interface protocol;
a second host interface configured to receive a second host request according to a second host interface protocol; and
a host translation layer configured to identify the first and second host interface protocols and to translate the first and second host requests into a meta request,
wherein the first host request and the second host request are for a same internal operation thereof.

15. The memory system of claim 14, wherein the host translation layer is configured to translate an internal operation completion signal suitable for the first or second host interface protocol based on identification when the same internal operation is completed.

16. The memory system of claim 14, wherein the first host interface protocol is one among a SAS interface protocol, a SATA interface protocol, a PCIe interface protocol, a UFS interface protocol, an NVMe interface protocol, and an eMMC interface protocol.

17. The memory system of claim 14, further comprising:
a nonvolatile memory device configured to store data; and
a flash control section configured to control the nonvolatile memory device based on the meta request.

18. The memory system of claim 17, wherein the flash control section is configured independently of differences between the first host interface protocol and the second host interface protocol.

19. The memory system of claim 14, wherein the host translation layer comprises an interface identification table and is configured to identify the first and second host interface protocols based on the interface identification table.

20. The memory system of claim 18, wherein the flash control section is configured to convert a logical address received from a host into a physical address based on an identified host interface protocol and control the nonvolatile memory device based on the physical address.
